(19) United States
(12) Patent Application Publication
(10) Pub. No.: US 2026/0156861 A1
(43) Pub. Date: Jun. 4, 2026

(54) SEMICONDUCTOR STRUCTURE

(71) Applicant: MEDIATEK INC., Hsinchu City (TW)

(72) Inventors: Bo-Yu WEI, Hsinchu City (TW); Je-Min WEN, Hsinchu City (TW); Yan-Liang JI, Hsinchu City (TW)

(21) Appl. No.: 19/328,529

(22) Filed: Sep. 15, 2025

Related U.S. Application Data
(60) Provisional application No. 63/726,680, filed on Dec. 2, 2024.

(51) Int. Cl. H10D 30/65; H10D 62/10; H10D 64/23; H10D 64/27

(52) U.S. Cl. CPC H10D 30/655; H10D 62/111; H10D 64/257; H10D 64/518

(57) ABSTRACT

A semiconductor structure includes a drift region formed in the substrate and having a first conductivity type. The semiconductor structure includes a body region formed in the substrate and having a second conductivity type different from the first conductivity type. The semiconductor structure includes a gate structure formed over the drift region and adjacent to the body region, and a drain region formed in the drift region and having the first conductivity type. The semiconductor structure includes a source region formed in the body region and having the first conductivity type, and a first well region adjacent to the drift region. The first well region has the first conductivity type. A second well region is adjacent to the first well region, and the second well region has the second conductivity type. The first well region is in direct contact with the second well region.

### CROSS REFERENCE TO RELATED APPLICATIONS

This Application claims the benefit of U.S. Provisional Application No. 63/726,680, filed on Dec. 2, 2024, the entirety of which is incorporated by reference herein.

### BACKGROUND OF THE INVENTION

### Field of the Invention

The present invention relates in general to semiconductor technology, and, in particular, it relates to a semiconductor structure.

### Description of the Related Art

Recently, as demand has increased for high-voltage devices such as power semiconductor devices, there has been an increasing interest in research on high-voltage metal-oxide-semiconductor field effect transistors (HV MOSFETs) applied in high-voltage devices.

Among the various types of high-voltage metal-oxide-semiconductor field effect transistors (HV MOSFETs), semiconductor devices such as lateral double diffused metal-oxide-semiconductor (LDMOS) devices are often used.

However, with progress being made in semiconductor fabrication, the breakdown voltage of high-voltage MOSFETs for high-voltage devices needs to be increased further. Thus, a reliable high-voltage MOSFET for high-voltage devices having an increased breakdown voltage is needed to meet device performance requirements as the needs of semiconductor fabrication of high-voltage devices continue.

### BRIEF SUMMARY OF THE INVENTION

Semiconductor structures are provided. An exemplary embodiment of a semiconductor structure includes a substrate, and a drift region formed in the substrate and having a first conductivity type. The semiconductor structure includes a body region formed in the substrate and having a second conductivity type. The second conductivity type is different from the first conductivity type. The semiconductor structure includes a gate structure formed over the drift region and adjacent to the body region, and a drain region formed in the drift region and having the first conductivity type. The semiconductor structure includes a source region formed in the body region and having the first conductivity type, and a first well region adjacent to the drift region. The first well region has the first conductivity type. The semiconductor structure includes a second well region adjacent to the first well region, and the second well region has the second conductivity type. The first well region is in direct contact with the second well region.

Another embodiment of a semiconductor structure includes a substrate, and a drift region formed in the substrate and having a first conductivity type. The semiconductor structure includes a body region formed in the substrate and having a second conductivity type different from the first conductivity type. The semiconductor structure includes a gate structure formed over the drift region, and a drain region formed in the drift region and having the first conductivity type. The semiconductor structure includes a source region formed in the body region and having the first conductivity type, and an inner ring surrounding the gate structure, the drain region and the source region, and the inner ring has the first conductivity type. The semiconductor structure includes an outer ring surrounding the inner ring, and the outer ring has the second conductivity type.

Yet another embodiment of a semiconductor structure includes substrate, and a drift region formed in a substrate and having a first conductivity type. The semiconductor structure includes a body region formed in the substrate and having a second conductivity type different from the first conductivity type. The semiconductor structure includes a gate structure formed over the drift region, and an inner ring surrounding the gate structure. The semiconductor structure includes an outer ring surrounding the inner ring, and the inner ring or the outer ring has a plurality of first sub-portions with the first conductivity type and a plurality of second sub-portions with the second conductivity type.

### BRIEF DESCRIPTION OF THE DRAWINGS

The present invention can be more fully understood by reading the subsequent detailed description and examples with references made to the accompanying drawings, wherein:

FIG. 1 is a cross-sectional view of a semiconductor structure, in accordance with some embodiments of the present disclosure;

FIG. 2 is a top view of the semiconductor structure along the line AA′ of FIG. 1, in accordance with some embodiments of the present disclosure;

FIG. 3 is a circuit diagram of a buck device, in accordance with some embodiments of the present disclosure;

FIG. 4 is a cross-sectional view of a semiconductor structure, in accordance with some embodiments of the present disclosure;

FIG. 5 is a top view of the semiconductor structure along the line AA′ of FIG. 4, in accordance with some embodiments of the present disclosure;

FIG. 6 is a cross-sectional view of a semiconductor structure, in accordance with some embodiments of the present disclosure;

FIG. 7 is a top view of the semiconductor structure along the line AA′ of FIG. 6, in accordance with some embodiments of the present disclosure;

FIG. 8 is a top view of a semiconductor structure, in accordance with some embodiments of the present disclosure;

FIG. 9 is a cross-sectional view of a semiconductor structure, in accordance with some embodiments of the present disclosure;

FIG. 10 is a top view of the semiconductor structure along the line AA′ of FIG. 9, in accordance with some embodiments of the present disclosure;

FIG. 11 is a cross-sectional view of a semiconductor structure, in accordance with some embodiments of the present disclosure;

FIG. 12 is a top view of the semiconductor structure along the line AA′ of FIG. 11, in accordance with some embodiments of the present disclosure;

FIG. 13 is a top view of a semiconductor structure, in accordance with some embodiments of the present disclosure.

### DETAILED DESCRIPTION OF THE INVENTION

The following description is made for the purpose of illustrating the general principles of the invention and should not be taken in a limiting sense. The scope of the invention is best determined by reference to the appended claims.

The present disclosure will be described with respect to particular embodiments and with reference to certain drawings, but the disclosure is not limited thereto and is only limited by the claims. The drawings described are only schematic and are non-limiting. In the drawings, the size of some of the elements may be exaggerated for illustrative purposes and not drawn to scale. The dimensions and the relative dimensions do not correspond to actual dimensions in the practice of the disclosure.

Additional elements may be added on the basis of the embodiments described below. For example, the description of “a first element on/over a second element” may include embodiments in which the first element is in direct contact with the second element, and may also include embodiments in which additional elements are disposed between the first element and the second element such that the first element and the second element are not in direct contact.

Furthermore, the description of “a first element extending through a second element” may include embodiments in which the first element is disposed in the second element and extends from a side of the second element to an opposite side of the second element, wherein a surface of the first element may be substantially leveled with a surface of the second element, or a surface of the first element may be outside a surface of the second element.

The spatially relative descriptors of the first element and the second element may change as the structure is operated or used in different orientations. In addition, the present disclosure may repeat reference numerals and/or letters in the various embodiments. This repetition is for simplicity and clarity and does not in itself dictate a relationship between the various embodiments discussed. For avoidance of doubts, the X direction, the Y direction, and the Z direction in the figures are perpendicular to one another and are used consistently.

A semiconductor structure includes an active region and a peripheral region, and a transistor is formed in the active region, a number of guard rings are formed at peripheral region. The transistor at the active region is surrounded by the guard rings. The guard rings can manage the breakdown path away from the active region. The guard rings may have two or three rings. The design of the guard rings to build a relative lower breakdown voltage than the breakdown voltage in the active region. The high voltage or high current will be connected to ground optional position (GND) through the guard rings. Therefore, the transistor at the active region is protected by the guard rings from being damaged.

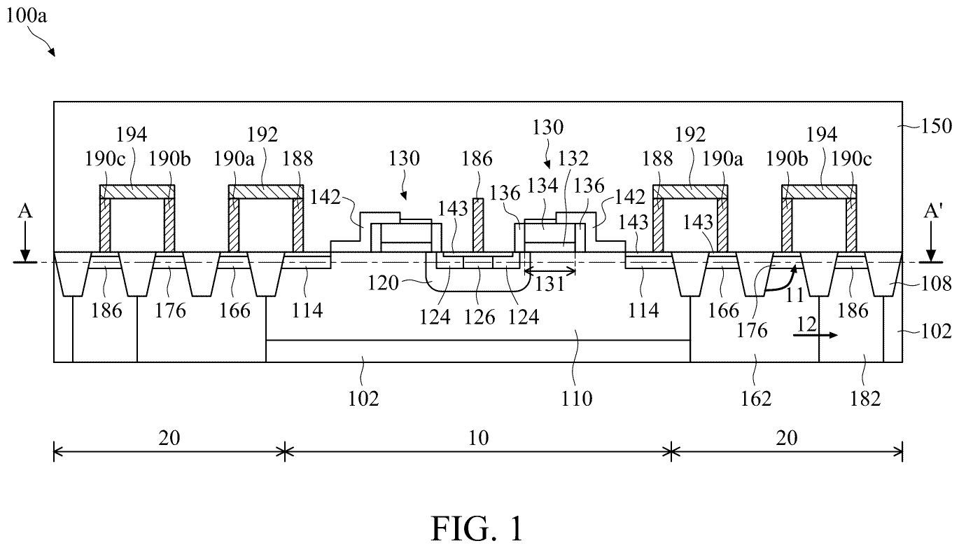

FIG. 1 is a cross-sectional view of a semiconductor structure 100a, in accordance with some embodiments of the present disclosure. Additional features can be added to the semiconductor structure 100a. Some of the features described below can be replaced or eliminated for different embodiments. To simplify the diagram, only a portion of the semiconductor structure 100a is illustrated. In some embodiments, the semiconductor structure 100a is a lateral diffused MOS (LDMOS) transistor.

As illustrated in FIG. 1, the semiconductor structure 100a includes a substrate 102, a drift region 110 and a body region 120, in accordance with some embodiments. The substrate 102 includes an active region 10 surrounded by a peripheral region 20. The drift region 110 is formed in the substrate 102 and has a first conductive type. The body region 120 is formed in the substrate 102 and has a second conductive type different from the first conductive type. In some embodiments, the drift region 110 has a N-type conductive type, and the body region 120 has a P-type conductive type. The semiconductor structure 100a is substantially symmetrical with respect with the body region 120.

The substrate 102 may include elementary semiconductor materials, compound semiconductor materials, and/or alloy semiconductor materials. Elementary semiconductor materials may include, but are not limited to, crystal silicon, polycrystalline silicon, amorphous silicon, germanium, and/or diamond. Compound semiconductor materials may include, but are not limited to, silicon carbide, gallium arsenic, gallium phosphide, indium phosphide, indium arsenide, and/or indium antimonide. Alloy semiconductor materials may include, but are not limited to, SiGe, GaAsP, AlInAs, AlGaAs, GaInAs, GaInP, and/or GaInAsP.

The semiconductor structure 100a further includes a plurality of isolation structures 108 in the substrate 102. The isolation regions are also referred to as shallow trench isolation (STI) features. In some embodiments, the isolation structures 108 includes silicon oxide, silicon nitride, silicon oxynitride (SiON), another suitable insulating material, or a combination thereof. In some embodiments, the isolation structures 108 is formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

The semiconductor structure 100a further includes a transistor, and the transistor includes a gate structure 130, a drain region 114 and a source region 124 formed on opposite sides of the gate structure 130. The drift region 110 is laterally between the source region 124 and the drain region 114.

The gate structure 130 includes a gate dielectric layer 132 and a gate electrode layer 134 formed on the gate dielectric layer 132. A pair of gate spacer layers 136 are formed on opposite sidewall surfaces of the gate structure 130. The gate electrode layer 134 is separated from the drift region 110 by the gate dielectric layer 132. A channel region 131 is directly below the gate structure 130 and between the source region 124 and the drain region 114.

In some embodiments, the dielectric constant of the gate dielectric layer 132 is greater than the dielectric constant of the gate spacer layer 136. In some embodiments, the gate dielectric layers 132 includes one or more layers of dielectric materials, such as HfO₂, HfSiO, HfSiON, HfTaO, HfTiO, HfZrO, zirconium oxide, aluminum oxide, titanium oxide, hafnium dioxide-alumina (HfO₂—Al2O₃) alloy, another suitable high-k dielectric material, or a combination thereof. In some embodiments, the gate dielectric layer 132 is formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

In some embodiments, the gate spacer layers 136 includes a dielectric material, such as silicon oxide (SiO₂), silicon nitride (SiN), silicon carbide (SiC), silicon oxynitride (SiON), silicon carbon nitride (SiCN), silicon oxide carbonitride (SiOCN), or a combination thereof. In some embodiments, the gate spacer layer 136 is formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

In some embodiments, the gate electrode layer 134 includes one or more layers of conductive material, such as aluminum, copper, titanium, tantalum, tungsten, cobalt, molybdenum, tantalum nitride, nickel silicide, cobalt silicide, TiN, WN, TiAl, TiAlN, TaCN, TaC, TaSiN, metal alloys, another suitable material, or a combination thereof. In some embodiments, the gate electrode layer 134 is formed using chemical vapor deposition (CVD), atomic layer deposition (ALD), electroplating, another applicable method, or a combination thereof.

Other conductive layers, such as work function metal layers, may also be formed in the gate structure 130, although they are not shown in the figures. In some embodiments, the n-work function layer includes tungsten (W), copper (Cu), titanium (Ti), silver (Ag), aluminum (Al), titanium nitride (TiN), tantalum nitride (TaN), tantalum carbide (TaC), titanium aluminum alloy (TiAl), titanium aluminum nitride (TiAlN), tantalum carbon nitride (TaCN), tantalum silicon nitride (TaSiN), manganese (Mn), zirconium (Zr) or a combination thereof. In some embodiments, the p-work function layer includes titanium (Ti), titanium nitride (TiN), tantalum nitride (TaN), tantalum carbide (TaC), molybdenum nitride, tungsten nitride (WN), ruthenium (Ru) or a combination thereof.

The drain region 114 is formed in the drift region 110 and has the first conductive type. In some embodiments, the drain region 114 is doped with a N-type dopant, and the drift region 110 is also doped with N-type dopants. In some embodiments, the doping concentration of the drain region 114 is greater than the doping concentration of the drift region 110. In some embodiments, the doping concentration of the drain region 114 is in a range from 10¹⁴/cm² to about 10¹⁵/cm². In some embodiments, the doping concentration of the drift region 110 is in a range about 3*10¹²/cm² to about 6*10¹²/cm².

The source region 124 is formed in the body region 120 and has the first conductive type. In some embodiments, the source region 124 is doped with a N-type dopant. In addition, a contact region 126 is formed in the body region 120 and adjacent to the source region 124. The contact region 126 is in direct contact with the source region 124. The contact region 126 has the second conductive type. In some embodiments, the contact region 126 is doped with a p-type dopant. In some embodiments, the doping concentration of the body region 120 is in a range from about 10¹³/cm² to about 10¹⁴/cm².

A silicide block layer 142 is formed on a portion of the gate structure 130 and a portion of the gate spacer layer 136 and on the substrate 102. More specifically, the silicide block layer 142 covers the top surface of the gate electrode layer 134 of the gate structure 130 and the sidewall surface of the gate spacer layer 136. In some embodiments, the silicide block layer 142 is configured to block the deposition of the silicide layers.

In some embodiments, the silicide block layer 142 includes oxide or nitride, such as silicon dioxide, silicon oxynitride, silicon nitride, or another applicable material. In some embodiments, the silicide block layer 142 is formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

After forming the silicide block layer 142, a metal silicide layer 143 is formed on the source region 124, the drain region 114 and at least a portion of the top surface of the gate electrode layer 134 of the gate structure 130 to reduce a contact resistance. The metal silicide layer 143 includes a material including one or more of CoSi, NiSi, PtSi or another applicable material.

The metal silicide layers 143 may be formed by forming a metal layer over the top surfaces of the source region 124, the drain region 114 and at least a portion of the top surface of the gate electrode layer 134 of the gate structure 130 and annealing the metal layer to form the metal silicide layers 143. The unreacted metal layer may be removed after the metal silicide layers 143 are formed.

A first well region 162 is formed adjacent to the drift region 110, and a second well region 182 is adjacent to the first well region 162. The first well region 162 is in direct contact with the drift region 110, and the first well region 162 is in direct contact with the second well region 182. The first well region 162 has the first conductive type, and the second well region 182 has the second conductive type. In some embodiments, the first well region 162 is doped with N-type, and the second well region 182 is doped with P-type. There is an interface (or PN interface or PN junction) between the first well region 162 and the second well region 182.

An inner ring 166, a middle ring 176 and an outer ring 186 are formed in the peripheral region 20. The gate structure 130, the source region 124 and the drain region 114 are surrounded by the inner ring 166, the middle ring 176 and the outer ring 186.

The inner ring 160 is formed in the first well region 162. The first well region 162 has the first conductive type and the inner ring 166 has the first conductive type. In some embodiments, the first well region 162 is doped with N-type, and the inner ring 166 is doped with N-type. In some embodiments, the doping concentration of the inner ring 166 is greater than the doping concentration of the first well region 162. In some embodiments, the doping concentration of drift region 110 is greater than doping concentration of the first well region 162. In some embodiments, the doping concentration of the inner ring 166 is in a range from 10¹⁴/cm² to about 10¹⁵/cm². In some embodiments, the doping concentration of the first well region 162 is in a range about 1*10¹²/cm² to about 2*10¹²/cm².

The middle ring 176 is formed adjacent to the inner ring 166. The middle ring 176 is also formed in the first well region 162. More specifically, the middle ring 176 has the second conductive type in the first well region 162. In some embodiments, the first well region 162 is doped with N-type, and the middle ring 176 is doped with P-type. There is an interface (or PN interface or PN junction) between the first well region 162 and the middle ring 176.

The isolation structure 108 is between the inner ring 166 and the middle ring 176. The inner ring 166 is separated from the middle ring 176 by the isolation structure 108. The depth of the isolation structure 108 is greater than the depth of the inner ring 166 and the depth of the middle ring 176. In other words, the bottom surface of the isolation structure 108 is lower than the bottom surface of the inner ring 166 and the bottom surface of the middle ring 176.

The outer ring 186 is formed adjacent to the middle ring 176, and the middle ring 176 is between the inner ring 166 and the outer ring 186. The inner ring 166 and the middle ring 176 are surrounded by the outer ring 186. The outer ring 186 is formed in a second well region 182. The second well region 182 has the second conductive type, and the outer ring 186 also has the second conductive type. In some embodiments, the second well region 182 is doped with P-type, and the outer ring 186 is doped with P-type.

The isolation structure 108 is between the middle ring 176 and the outer ring 186. In addition, the isolation structure 108 is between the first well region 162 and the second well region 182. The middle ring 176 is separated from the outer ring 186 by the isolation structure 108. The depth of the isolation structure 108 is greater than the depth of the middle ring 176 and the depth of the outer ring 186. In other words, the bottom surface of the isolation structure 108 is lower than the bottom surface of the middle ring 176 and the bottom surface of the outer ring 186.

A dielectric layer 150 is formed over the gate structure 130, the drain region 114 and the source region 124. The dielectric layer 150 may include multilayers made of multiple dielectric materials, such as silicon oxide, silicon nitride, silicon oxynitride, phosphosilicate glass (PSG), borophosphosilicate glass (BPSG), and/or other applicable low-k dielectric materials. The dielectric layer 150 may be formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

In addition, one or more etch stop layers (not shown) may be formed in the dielectric layer 150 to use as an etch stop layer during the etching process. The etch stop layer includes a dielectric material, such as silicon nitride, silicon oxide, silicon oxynitride, another suitable dielectric material, or a combination thereof. The etch stop layer is formed by a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

A contact structure 186 is formed in the dielectric layer 150. In addition, the contact structure 186 is formed over the contact region 126, and the metal silicide layer 143 is between the contact region 126 and the contact structure 186. The contact region 126 is electrically connected to the contact structure 186 by the silicide layer 143.

The contact structure 186 includes conductive materials, such as copper, tungsten, aluminum, silver, or a combination thereof. In some embodiments, the conductive material is formed by performing a deposition process, such as chemical vapor deposition (CVD), physical vapor deposition, (PVD), atomic layer deposition (ALD), or other applicable processes.

The diffusion barrier layer may be formed before forming the conductive materials. In some embodiments, the diffusion barrier layer is made of made of titanium (Ti), titanium nitride (TiN), tantalum (Ta), tantalum nitride (TaN), or another applicable material. In some embodiments, the diffusion barrier layer is formed by using a process such as chemical vapor deposition (CVD), physical vapor deposition (PVD), plasma enhanced CVD (PECVD), plasma enhanced physical vapor deposition (PEPVD), atomic layer deposition (ALD), or any other applicable deposition processes.

In some embodiments, the contact openings is formed through the dielectric layer 150. The contact openings may be formed using a photolithography process and an etching process. Next, the diffusion barrier layer and the conductive materials are filled into the contact openings to form the contact structure 186.

A drain contact structure 188 is formed in the dielectric layer 150. In addition, the drain contact structure 188 is formed over the drain region 114, and the metal silicide layer 143 is between the drain region 114 and the drain contact structure 188. The drain region 114 is electrically connected to the drain contact structure 188 by the metal silicide layer 143. The drain contact structure 188 includes conductive materials, such as copper, tungsten, aluminum, silver, or a combination thereof.

An inner contact structure 190a, a middle contact structure 190b and an outer contact structure 190c are formed in the dielectric layer 150. In addition, the inner contact structure 190a is formed on and electrically connected to the inner ring 186. The middle contact structure 190b is formed on and electrically connected to the middle ring 17. The outer contact structure 190c is formed on and electrically connected to the outer ring 186. The middle contact structure 190b is between the inner contact structure 190a and the outer contact structure 190c. The inner contact structure 190a, the middle contact structure 190b and the outer contact structure 190c includes conductive materials, such as copper, tungsten, aluminum, silver, or a combination thereof.

A conductive layer 192 is formed over the drain region 114 and the inner ring 166. The conductive layer 192 is formed on and electrically connected to the drain contact structure 188 and the inner contact structure 190a. The conductive layer 192 is electrically connected to the high voltage (HV). The conductive layer 192 includes conductive materials, such as copper, tungsten, aluminum, silver, or a combination thereof.

A conductive layer 194 is formed over the second ring 176 and the outer ring 186. The conductive layer 194 is formed on and electrically connected to the middle contact structure 190b and the outer contact structure 190c. The conductive layer 194 is electrically connected to the ground potential position (GND). The inner contact structure 190a is electrically isolated from the outer contact structure 190c. The conductive layer 192 is electrically isolated from the conductive layer 194. The conductive layer 194 includes conductive materials, such as copper, tungsten, aluminum, silver, or a combination thereof.

As shown in FIG. 1, since the first well region 162 and the middle ring 176 are doped with different conductive type, there is a first interface (PN interface or PN junction) between the first well region 162 and the middle ring 176. In addition, since the first well region 162 and the second well region 182 are doped with different conductive type, there is a second interface (PN interface or PN junction) between the first well region 162 and the second well region 182.

In some embodiments, when the high voltage (HV) is connected to the drain contact structure 188 and the inner contact structure 190a, and the ground potential position (GND) is connected to the middle contact structure 190b and the outer contact structure 190c, a first breakdown path 11 passes through the first interface between the first well region 162 and the middle ring 176. In addition, a second breakdown path 12 passes through the second interface between the first well region 162 and the second well region 182. Since the middle ring 176 has a higher doping concentration than the second well region 182, the first breakdown voltage through the first breakdown path 11 is lower than the second breakdown voltage through the second breakdown path 12. As a result, the high voltage or high current can be connected to the ground potential position (GND) through the first breakdown path 11 or the second breakdown path 12. Therefore, the gate structure 130 of the transistor in the active region 10 is protected by the design of the inner ring 166, the middle ring 176 and the outer ring 186. The transistor in the active region 10 is not be damaged when the semiconductor structure 100a is operated at high voltage.

As mentioned above, the first breakdown path 11 or the second breakdown path 12 are constructed by forming the PN junction or PN interface. The first breakdown path 11 or the second breakdown path 12 can effectively conduct the high voltage or high current to ground optional position (GND). Therefore, the transistor in the active region 10 can be protected from being damaged and the performance of the semiconductor structures 100a is improved.

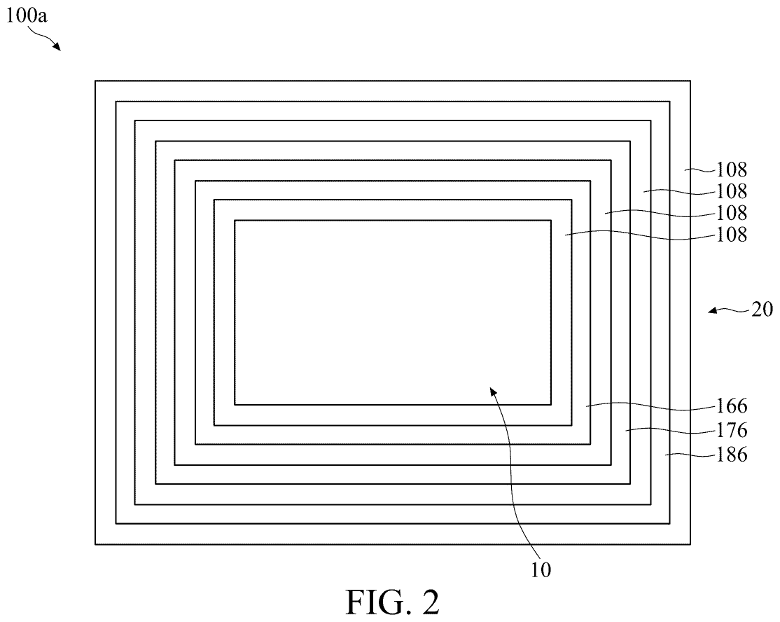

FIG. 2 is a top view of the semiconductor structure 100a along the line AA′ of FIG. 1, in accordance with some embodiments of the present disclosure. An active region 10 is surrounded by a peripheral region 20. The gate structure 130, the source region 124 and the drain region 114 are formed in the active region 10. The inner ring 116, the middle ring 176 and the outer ring 186 are formed in the peripheral region 20. The detail structures in the active region 10 is not shown for clarity.

As shown in FIG. 2, the active region 10 is surrounded by the inner ring 166, the middle ring 176 and the outer ring 186. The isolation structure 108 is between the inner ring 166 and the middle ring 176. The isolation structure 108 is between the middle ring 176 and the outer ring 186. The isolation structures 108 are forms multiple rings when seen from a top-view.

It should be noted that the inner ring 166, the middle ring 176 and the outer ring 186 are for illustrative purposes only, and more rings may be disposed in the peripheral region 20 of the semiconductor structure 100a.

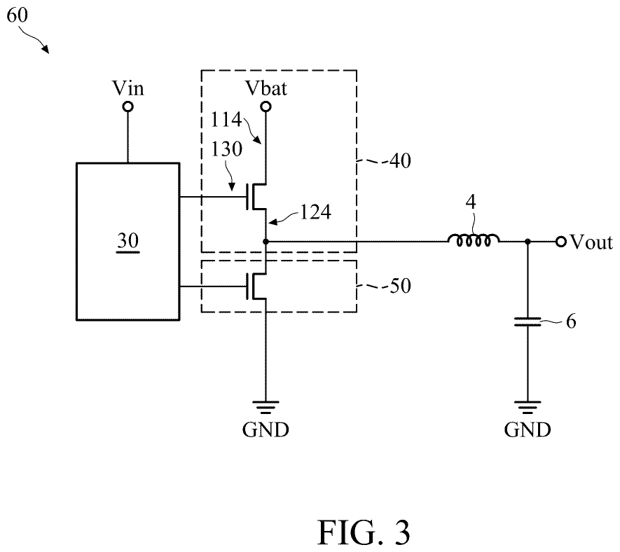

FIG. 3 is a circuit diagram of a buck converter device 60, in accordance with some embodiments of the present disclosure. The buck converter device 60 includes the transistor of the semiconductor structure 100a as shown in FIGS. 1 and 2.

The buck converter device 60 includes a buck controller 30, a high voltage side (HS) device 40 and a low voltage side (LS) device 50. The input terminal Vin is connected to the buck controller 30, and the buck controller 30 is connected to the high voltage side (HS) device 40 and the low voltage side (LS) device 50. The high voltage side (HS) device 40 includes the transistor of the semiconductor structure 100a. The transistor of the semiconductor structure 100a includes the gate structure 130, the drain region 114 and the source region 124. The battery terminal Vbat is connected to the drain region 114, the buck controller 30 is connected to the gate structure 130, and the source region 124 is connected to the low voltage side (LS) device 50 and the inductor 4. The inductor 4 is connected to the output terminal Vout and through a capacitor 6 to the ground (GND).

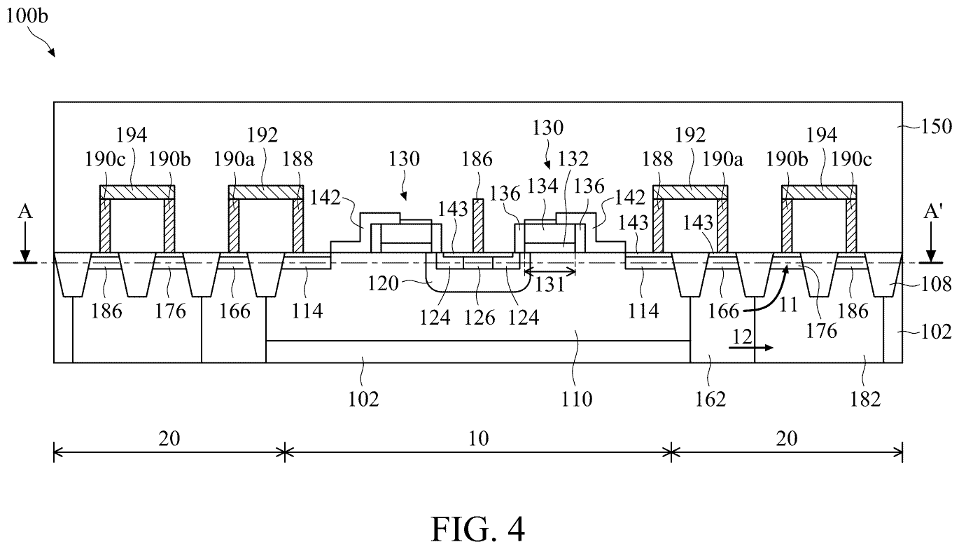

FIG. 4 is a cross-sectional view of a semiconductor structure 100b, in accordance with some embodiments of the present disclosure. Additional features can be added to the semiconductor structure 100b. Some of the features described below can be replaced or eliminated for different embodiments. It should be noted that the semiconductor structure 100b may include the same or similar components as those of the semiconductor structure 100a, which is illustrated in FIG. 1, and for the sake of simplicity, those components will not be discussed in detail again.

The semiconductor structure 100b of FIG. 4 includes elements that are similar to, or the same as, elements of the semiconductor structure 100a of FIG. 1, the difference between FIG. 4 and FIG. 1 is that the middle ring 176 is in the second well region 182 and has the first conductivity type. In some embodiments, the middle ring 176 is doped with N-type, and the second well region 182 is doped with P-type. As a result, an interface (or PN interface or PN junction) between the middle ring 176 and the second well region 182.

As shown in FIG. 4, when the high voltage (HV) is connected to the drain contact structure 188 and the inner contact structure 190a, and the ground potential position (GND) is connected to the middle contact structure 190b and the outer contact structure 190c, a first breakdown path 11 passes through the first well region 162 and the middle ring 176. In addition, a second breakdown path 12 passes through the second interface between the first well region 162 and the second well region 182.

In some embodiments, the first breakdown voltage through the first breakdown path 11 can be adjusted by controlling the distance between the first well region 162 and the middle ring 176. In some other embodiments, the first breakdown voltage through the first breakdown path 11 can be adjusted by controlling the doping concentration of the middle ring 176.

Similar to the semiconductor structure 100a of FIG. 1, the first breakdown voltage through the first breakdown path 11 is lower than the second breakdown voltage through the second breakdown path 12. As a result, the high voltage or high current can be connected to the ground potential position (GND) through the first breakdown path 11 or the second breakdown path 12. Therefore, the gate structure 130 of the transistor in the active region 10 is protected by the design of the inner ring 166, the middle ring 176 and the outer ring 186. The transistor in the active region 10 is not be damaged when the semiconductor structure 100b is operated at high voltage.

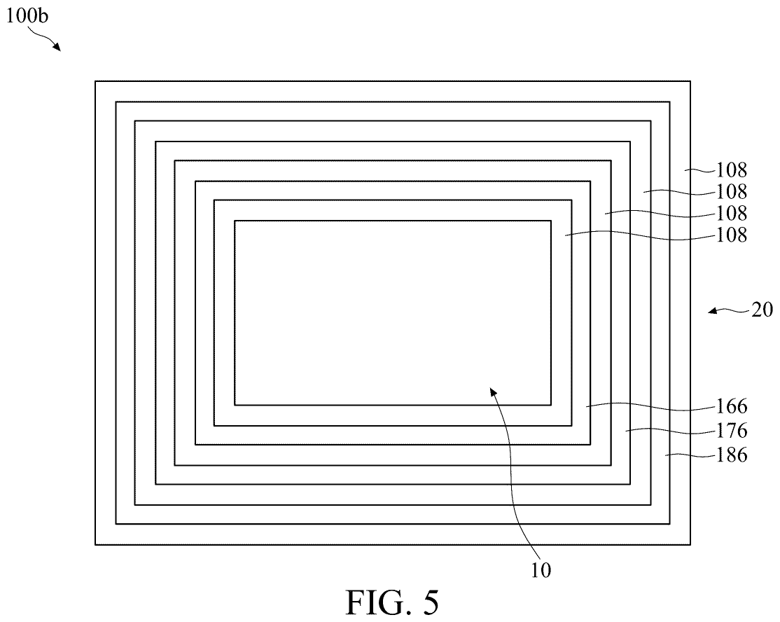

FIG. 5 is a top view of the semiconductor structure 100b along the line AA′ of FIG. 4, in accordance with some embodiments of the present disclosure.

As shown in FIG. 5, the active region 10 is surrounded by the inner ring 166, the middle ring 176 and the outer ring 186. The isolation structure 108 is between the inner ring 166 and the middle ring 176. The isolation structure 108 is between the middle ring 176 and the outer ring 186. The isolation structures 108 are forms multiple rings when seen from a top-view.

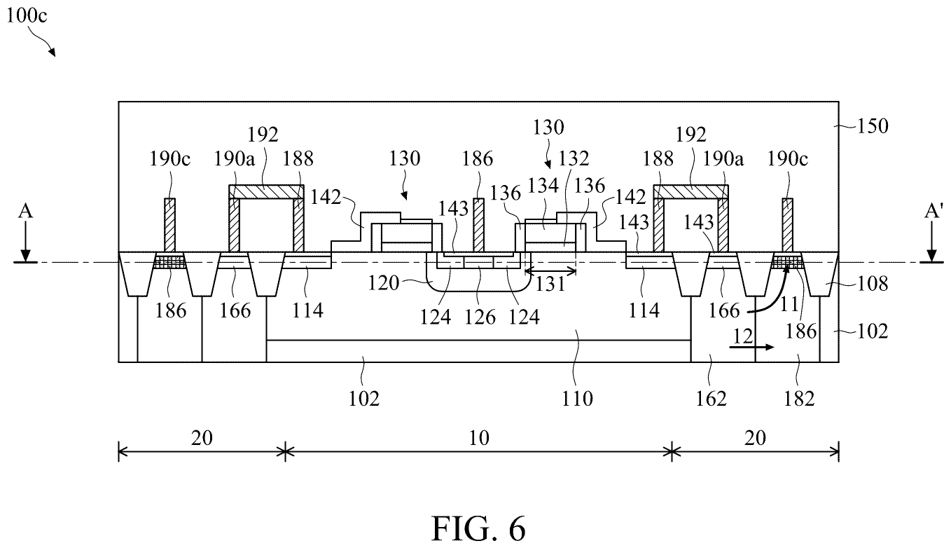

FIG. 6 is a cross-sectional view of a semiconductor structure 100c, in accordance with some embodiments of the present disclosure. Additional features can be added to the semiconductor structure 100c. Some of the features described below can be replaced or eliminated for different embodiments. It should be noted that the semiconductor structure 100c may include the same or similar components as those of the semiconductor structure 100a, which is illustrated in FIG. 1, and for the sake of simplicity, those components will not be discussed in detail again.

The semiconductor structure 100c of FIG. 6 includes elements that are similar to, or the same as, elements of the semiconductor structure 100a of FIG. 1, the difference between FIG. 6 and FIG. 1 is that there is no middle ring and the outer ring 186 includes a plurality of first sub-portions 186a with the first conductivity type and a plurality of second sub-portions 186b with the second conductivity type formed in the second well region 182. The inner ring 166 is surrounded by the outer ring 186. The inner ring 166 is formed in the first well region 162, and the outer ring 186 is formed in the second well region 182. The first well region 162 is in direct contact with the second well region 182.

The first sub-portions 186a and the second sub-portions 186b are alternatively arranged. In some embodiments, the area of each of the first sub-portions 186a is substantially equal to the area of each of the second sub-portions 186b.

When the high voltage (HV) is connected to the drain contact structure 188 and the inner contact structure 190a, and the ground potential position (GND) is connected to the outer contact structure 190c, a first breakdown path 11 passes through the first well region 162 and the outer ring 186. In addition, a second breakdown path 12 passes through the second interface between the first well region 162 and the second well region 182.

In some embodiments, the first breakdown voltage through the first breakdown path 11 can be adjusted by controlling the distance between the first well region 162 and the outer ring 186. In some other embodiments, the first breakdown voltage through the first breakdown path 11 can be adjusted by controlling the doping concentration of the first sub-portions 186a and the second sub-portions 186b of the middle ring 176.

Similar to the semiconductor structure 100a of FIG. 1, the first breakdown voltage through the first breakdown path 11 is lower than the second breakdown voltage through the second breakdown path 12. As a result, the high voltage or high current can be connected to the ground potential position (GND) through the first breakdown path 11 or the second breakdown path 12. Therefore, the gate structure 130 of the transistor in the active region 10 is protected by the design of the inner ring 166, the middle ring 176 and the outer ring 186. The transistor in the active region 10 is not be damaged when the semiconductor structure 100c is operated at high voltage.

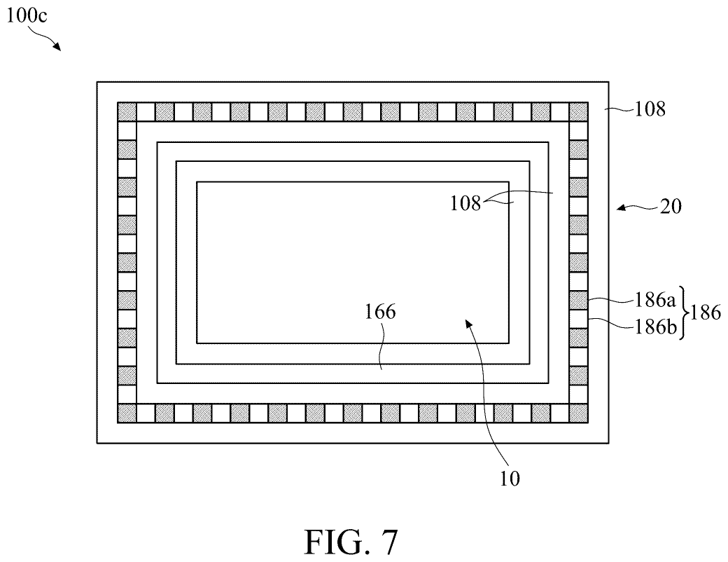

FIG. 7 is a top view of the semiconductor structure 100c along the line AA′ of FIG. 6, in accordance with some embodiments of the present disclosure. It should be noted that the active region 10 is surrounded by two rings, not through rings. The active region 10 is surrounded by the inner ring 166 and the outer ring 186. The sidewall surface of the first sub-portions 186a of the outer ring 186 is adjacent to and in direct contact with the sidewall surface of the second sub-portions 186b of the outer ring 186.

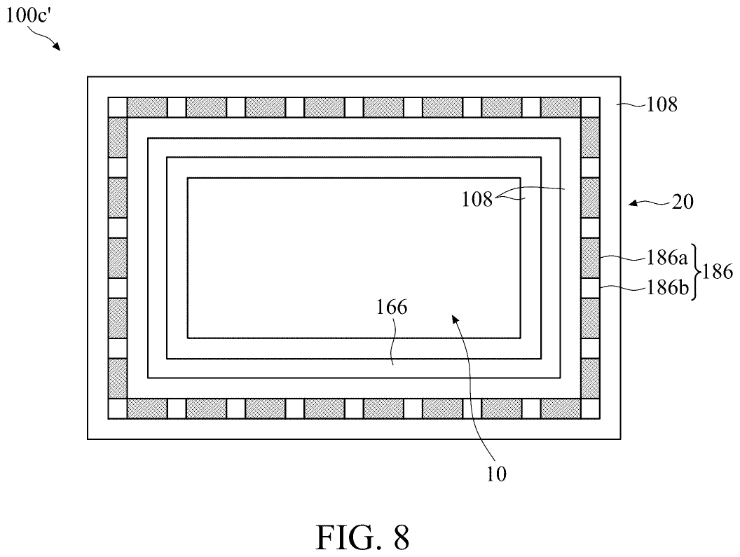

FIG. 8 is a top view of a semiconductor structure 100c′, in accordance with some embodiments of the present disclosure. The semiconductor structure 100c′ of FIG. 8 includes elements that are similar to, or the same as, elements of the semiconductor structure 100c of FIG. 7, the difference between FIG. 8 and FIG. 7 is that the area of the first sub-portions 186a is greater than to the area of each of the second sub-portions 186b. In some embodiments, a ratio of the area of the first sub-portions 186a with respect to the area of the second sub-portions 186b is in a range from about 2 to about 1.

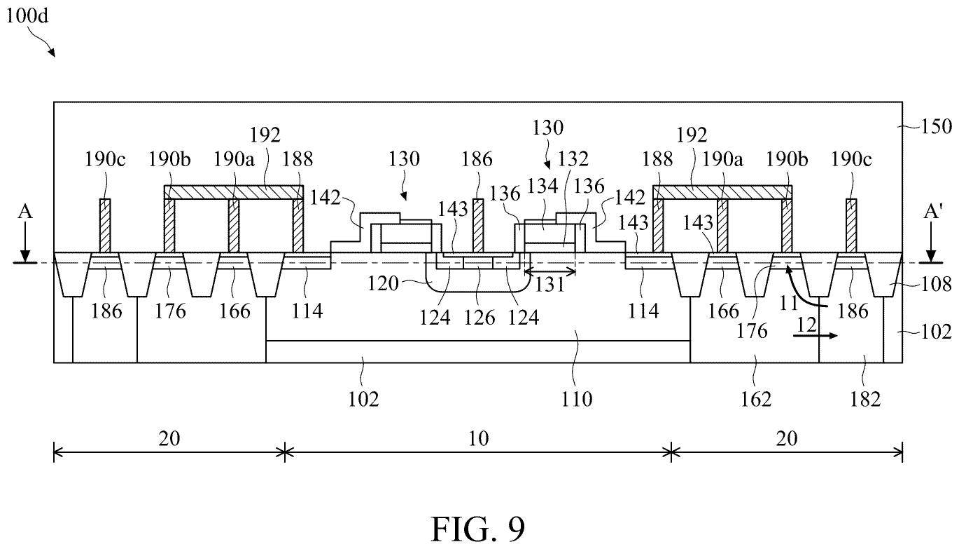

FIG. 9 is a cross-sectional view of a semiconductor structure 100d, in accordance with some embodiments of the present disclosure. Additional features can be added to the semiconductor structure 100d. Some of the features described below can be replaced or eliminated for different embodiments. It should be noted that the semiconductor structure 100d may include the same or similar components as those of the semiconductor structure 100a, which is illustrated in FIG. 1, and for the sake of simplicity, those components will not be discussed in detail again.

The semiconductor structure 100d of FIG. 9 includes elements that are similar to, or the same as, elements of the semiconductor structure 100a of FIG. 1, the difference between FIG. 9 and FIG. 1 is that the high voltage (HV) is connected to the drain contact structure 188, the inner contact structure 190a and the middle contact structure 190b, and the ground potential position (GND) is connected the outer contact structure 190c. In addition, the middle ring 176 has the second conductive type. In some embodiments, the middle ring 176 is doped with P-type. There is an interface (or PN interface or PN junction) between the first well region 162 and the middle ring 176.

The first breakdown path 11 passes through the middle ring 176 and the second well region 182. In addition, the second breakdown path 12 passes through the second interface between the first well region 162 and the second well region 182.

In some embodiments, the first breakdown voltage through the first breakdown path 11 can be adjusted by controlling the distance between the middle ring 176 and the second well region 182. In some other embodiments, the first breakdown voltage through the first breakdown path 11 can be adjusted by controlling the doping concentration of the middle ring 176.

Similar to the semiconductor structure 100a of FIG. 1, the first breakdown voltage through the first breakdown path 11 is lower than the second breakdown voltage through the second breakdown path 12. As a result, the high voltage or high current can be connected to the ground potential position (GND) through the first breakdown path 11 or the second breakdown path 12. Therefore, the gate structure 130 of the transistor in the active region 10 is protected by the design of the inner ring 166, the middle ring 176 and the outer ring 186. The transistor in the active region 10 is not be damaged when the semiconductor structure 100d is operated at high voltage.

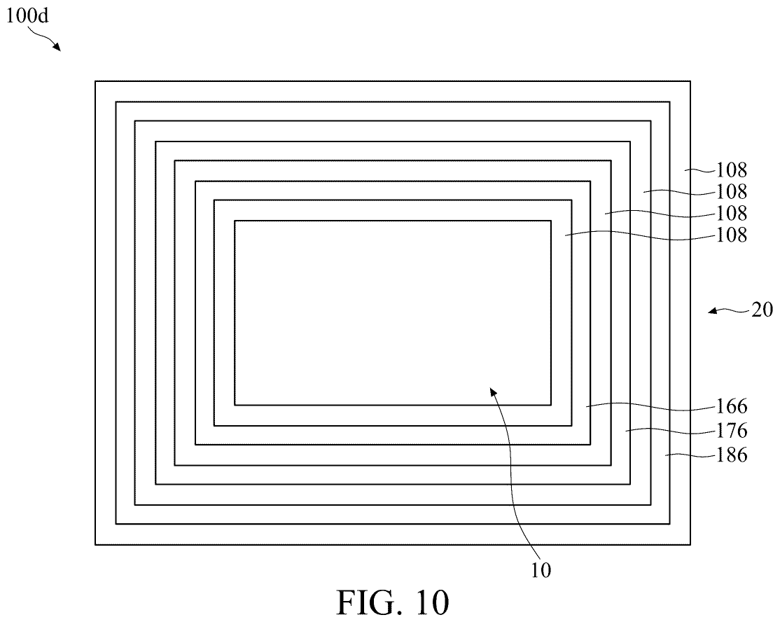

FIG. 10 is a top view of the semiconductor structure 100d along the line AA′ of FIG. 9, in accordance with some embodiments of the present disclosure. It should be noted that the active region 10 is surrounded by the inner ring 166, the middle ring 176 and the outer ring 186.

The isolation structure 108 is between the inner ring 166 and the middle ring 176. The isolation structure 108 is between the middle ring 176 and the outer ring 186. The isolation structures 108 are forms multiple rings when seen from a top-view.

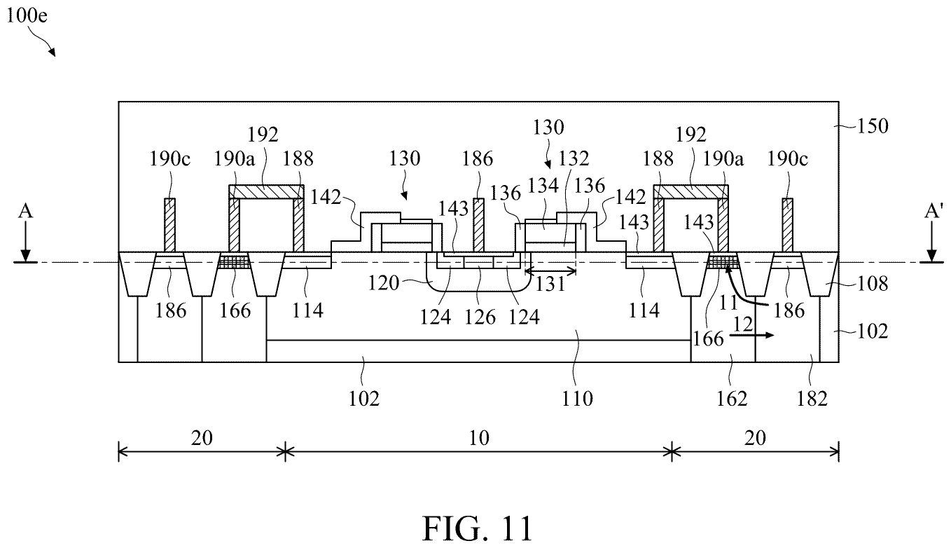

FIG. 11 is a cross-sectional view of a semiconductor structure 100e, in accordance with some embodiments of the present disclosure. Additional features can be added to the semiconductor structure 100e. Some of the features described below can be replaced or eliminated for different embodiments. It should be noted that the semiconductor structure 100e may include the same or similar components as those of the semiconductor structure 100a, which is illustrated in FIG. 1, and for the sake of simplicity, those components will not be discussed in detail again.

The semiconductor structure 100e of FIG. 11 includes elements that are similar to, or the same as, elements of the semiconductor structure 100a of FIG. 1, the difference between FIG. 11 and FIG. 1 is that the inner ring 166 includes a plurality of first sub-portions 166a with the first conductivity type and a plurality of second sub-portions 166b with the second conductivity type formed in the first well region 162. The first sub-portions 166a and the second sub-portions 166b are alternatively arranged. In some embodiments, the area of each of the first sub-portions 166a is substantially equal to the area of each of the second sub-portions 166b. In addition, there is no middle ring in the semiconductor structure 100f.

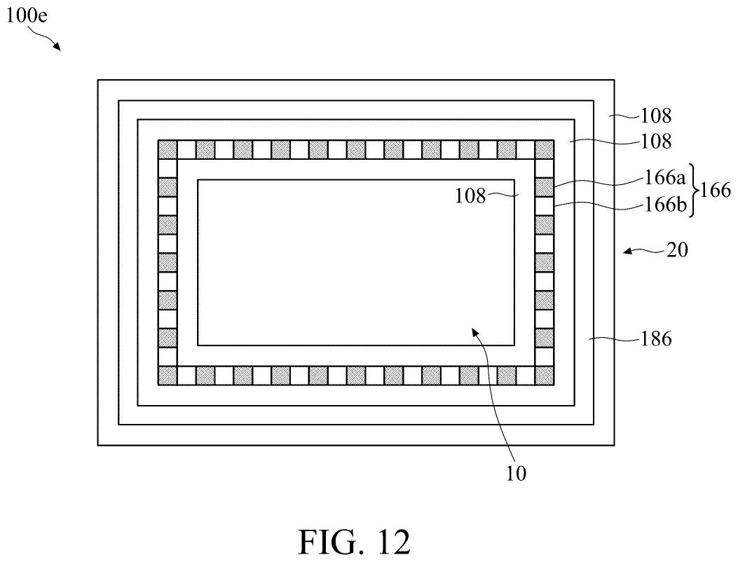

FIG. 12 is a top view of the semiconductor structure 100e along the line AA′ of FIG. 11, in accordance with some embodiments of the present disclosure. It should be noted that the active region 10 is surrounded by two rings, not through rings. The active region 10 is surrounded by the inner ring 166 and the outer ring 186. The sidewall surface of the first sub-portions 166a of the inner ring 166 is adjacent to and in direct contact with the sidewall surface of the second sub-portions 166b of the inner ring 166.

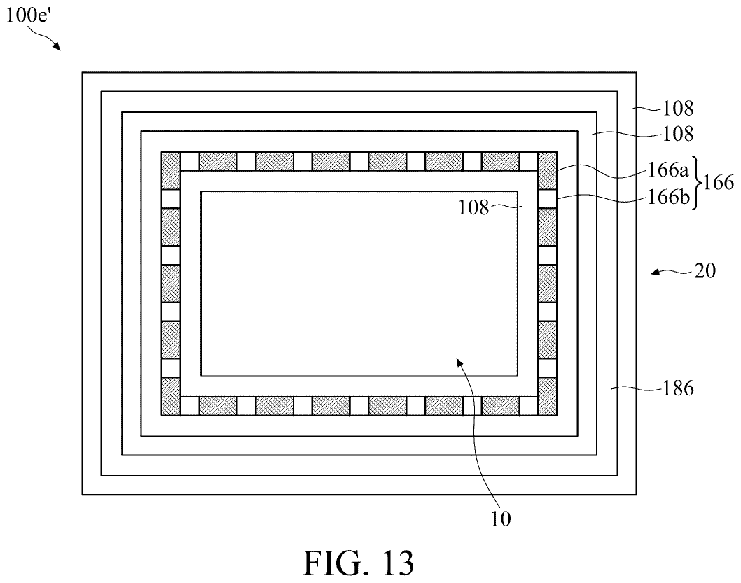

FIG. 13 is a top view of a semiconductor structure 100e′, in accordance with some embodiments of the present disclosure. The semiconductor structure 100e′ of FIG. 13 includes elements that are similar to, or the same as, elements of the semiconductor structure 100e of FIG. 12, the difference between FIG. 13 and FIG. 12 is that the area of the first sub-portions 166a is greater than to the area of each of the second sub-portions 166b. In some embodiments, a ratio of the area of the first sub-portions 166a with respect to the area of the second sub-portions 166b is in a range from about 2 to about 1.

As described previously, the semiconductor structures 100a-100e′ may include two rings or three rings to protect the semiconductor structures 100a-100e′ from being damaged.

In the embodiments illustrated in FIGS. 1 and 2, the semiconductor structure 100a includes inner ring 166, the middle ring 176 and the outer ring 186. The first breakdown path 11 or the second breakdown path 12 are constructed by forming the PN junction or PN interface.

In the embodiments illustrated in FIGS. 4 and 5, the semiconductor structure 100b includes inner ring 166, the middle ring 176 and the outer ring 186.

In the embodiments illustrated in FIGS. 6, 7 and 8, the semiconductor structure 100c and 100c′ includes inner ring 166 and the outer ring 186. The outer ring 186 includes a plurality of first sub-portions 186a with the first conductivity type and a plurality of second sub-portions 186b with the second conductivity type formed in the second well region 182.

In the embodiments illustrated in FIGS. 9 and 10, the semiconductor structure 100d includes inner ring 166, the middle ring 176 and the outer ring 186.

In the embodiments illustrated in FIGS. 11, 12 and 13, the semiconductor structure 100e and 100e′ includes inner ring 166 and the outer ring 186. The inner ring 166 includes a plurality of first sub-portions 166a with the first conductivity type and a plurality of second sub-portions 166b with the second conductivity type formed in the first well region 162.

The design of the guard rings 166, 176 and 186 of the semiconductor structures 100a-100e′ between the isolating structures 108 allows the breakdown to be spaced from the transistor in the active region 10. The first breakdown path 11 or the second breakdown path 12 are constructed by forming the PN junction or PN interface. The first breakdown path 11 or the second breakdown path 12 can effectively conduct the high voltage or high current to ground optional position (GND). Therefore, the transistor in the active region can be protected from being damaged and the performance of the semiconductor structures 100a-100e′ is improved.

In summary, the semiconductor structure according to the present disclosure includes a substrate, and a drift region formed in the substrate and having a first conductivity type. The semiconductor structure includes a body region formed in the substrate and having the second conductivity type. The semiconductor structure includes a gate structure formed over the drift region and adjacent to the body region, and a drain region formed in the drift region and having the first conductivity type. The semiconductor structure includes a source region formed in the body region and having the first conductivity type, and a first well region adjacent to the drift region. The first well region has the first conductivity type. The semiconductor structure includes a second well region adjacent to the first well region, and the second well region has the second conductivity type. The first well region is in direct contact with the second well region.

In summary, the semiconductor structure according to the present disclosure includes a substrate, and a drift region formed in the substrate and having a first conductivity type. The semiconductor structure includes a body region formed in the substrate and having a second conductivity type different from the first conductivity type. The semiconductor structure includes a gate structure formed over the drift region, and a drain region formed in the drift region and having the first conductivity type. The semiconductor structure includes a source region formed in the body region and having the first conductivity type, and an inner ring surrounding the gate structure, the drain region and the source region, and the inner ring has the first conductivity type. The semiconductor structure includes an outer ring surrounding the inner ring, and the outer ring has the second conductivity type.

In summary, the semiconductor structure according to the present disclosure includes a substrate, and a drift region formed in a substrate and having a first conductivity type. The semiconductor structure includes a body region formed in the substrate and having a second conductivity type different from the first conductivity type. The semiconductor structure includes a gate structure formed over the drift region, and an inner ring surrounding the gate structure. The semiconductor structure includes an outer ring surrounding the inner ring, and the inner ring or the outer ring has a plurality of first sub-portions with the first conductivity type and a plurality of second sub-portions with the second conductivity type.

While the invention has been described by way of example and in terms of the preferred embodiments, it should be understood that the invention is not limited to the disclosed embodiments. On the contrary, it is intended to cover various modifications and similar arrangements (as would be apparent to those skilled in the art). Therefore, the scope of the appended claims should be accorded the broadest interpretation so as to encompass all such modifications and similar arrangements.

What is claimed is:

1. A semiconductor structure, comprising:
a substrate;
a drift region formed in the substrate and having a first conductivity type;
a body region formed in the substrate and having a second conductivity type different from the first conductivity type;
a gate structure formed over the drift region and adjacent to the body region;
a drain region formed in the drift region and having the first conductivity type;
a source region formed in the body region and having the first conductivity type;
a first well region adjacent to the drift region, wherein the first well region has the first conductivity type; and
a second well region adjacent to the first well region, wherein the second well region has the second conductivity type, and the first well region is in direct contact with the second well region.

2. The semiconductor structure as claimed in claim 1, further comprising:
an inner ring formed in the first well region, wherein the inner ring has the first conductivity type.

3. The semiconductor structure as claimed in claim 1, further comprising:
an outer ring formed in the second well region, wherein the outer ring has the second conductive type.

4. The semiconductor structure as claimed in claim 1, further comprising:
an isolation structure between the first well region and the second well region.

5. The semiconductor structure as claimed in claim 1, further comprising:
an inner ring adjacent to the drain region;
a middle ring adjacent to the inner ring; and
an outer ring adjacent to the middle ring, wherein the middle ring is between the inner ring and the outer ring.

6. The semiconductor structure as claimed in claim 5, wherein the middle ring has the second conductivity type and is formed in the first well region.

7. The semiconductor structure as claimed in claim 5, wherein the middle ring has the first conductive type and is formed in in the second well region.

8. The semiconductor structure as claimed in claim 1, further comprising:
an inner ring adjacent to the drain region, wherein the inner ring comprises a plurality of first sub-portions with the first conductivity type and a plurality of second sub-portions with the second conductivity type formed in the first well region.

9. The semiconductor structure as claimed in claim 1, further comprising:
an outer ring adjacent to the drain region, wherein the outer ring comprises a plurality of first sub-portions with the first conductivity type and a plurality of second sub-portions with the second conductivity type formed in the second well region.

10. The semiconductor structure as claimed in claim 1, further comprising:
a drain contact structure formed on the drain region;
an inner ring adjacent to the drain region;
an inner contact structure formed on the inner ring; and
a conductive layer formed on the drain contact structure and the inner contact structure.

11. A semiconductor structure, comprising:
a substrate;
a drift region formed in the substrate and having a first conductivity type;
a body region formed in the substrate and having a second conductivity type different from the first conductivity type;
a gate structure formed over the drift region;
a drain region formed in the drift region and having the first conductivity type;
a source region formed in the body region and having the first conductivity type;
an inner ring surrounding the gate structure, the drain region and the source region, wherein the inner ring has the first conductivity type; and
an outer ring surrounding the inner ring, wherein the outer ring has the second conductivity type.

12. The semiconductor structure as claimed in claim 11, wherein the inner ring is formed in a first well region, and the outer ring is formed in a second well region, wherein the first well region is in direct contact with the second well region.

13. The semiconductor structure as claimed in claim 11, further comprising:
a middle ring between the inner ring and the outer ring, wherein the middle ring has the first conductivity type or the second conductivity type.

14. The semiconductor structure as claimed in claim 11, wherein the inner ring comprises a plurality of first sub-portions with the first conductivity type and a plurality of second sub-portions with the second conductivity type.

15. The semiconductor structure as claimed in claim 11, wherein the outer ring comprises a plurality of first sub-portions with the first conductivity type and a plurality of second sub-portions with the second conductivity type.

16. The semiconductor structure as claimed in claim 11, further comprising:
a drain contact structure formed on the drain region;
an inner contact structure formed on the inner ring; and
a conductive layer formed on the drain contact structure and the inner contact structure.

17. The semiconductor structure as claimed in claim 11, further comprising:
an outer contact structure formed on the outer ring, wherein the outer contact structure is connected to a ground potential position.

18. A semiconductor structure, comprising:
a drift region formed in a substrate and having a first conductivity type;
a body region formed in the substrate and having a second conductivity type different from the first conductivity type;
a gate structure formed over the drift region;
an inner ring surrounding the gate structure; and
an outer ring surrounding the inner ring, wherein the inner ring or the outer ring comprises a plurality of first sub-portions with the first conductivity type and a plurality of second sub-portions with the second conductivity type.

19. The semiconductor structure as claimed in claim 18, wherein an area of the first sub-portions is equal to or greater than an area of the second sub-portions.

20. The semiconductor structure as claimed in claim 18, further comprising:
an inner contact structure formed on the inner ring; and
an outer contact structure formed on the outer ring, wherein the inner contact structure is electrically isolated from the outer contact structure.
